(19) United States
(12) Patent Application Publication
(10) Pub. No.: US 2012/0320525 A1
(43) Pub. Date: Dec. 20, 2012

(54) ELECTRONIC SYSTEM COMPRISING A FIXED STRUCTURE INCLUDING A CASING FOR PROTECTING ELECTRONIC EQUIPMENT AND A MOBILE STRUCTURE RELATIVELY TO THE FIXED STRUCTURE, THE MOBILE STRUCTURE INCLUDING AN AIR SUCTION APERTURE

(75) Inventors: Christophe Vedel, Rungis (FR); Olivier Dez, Rungis (FR); Nicolas Barbier, Rungis (FR)

(73) Assignee: THALES, NEUILLY SUR SIENE (FR)

(21) Appl. No.: 13/526,169

(22) Filed: Jun. 18, 2012

(30) Foreign Application Priority Data
Jun. 17, 2011 (FR) 1101874

(51) Int. Cl. H05K 7/20

(52) U.S. Cl. 361/690

(57) ABSTRACT

This electronic system comprises :
a fixed structure including a protective casing and electronic equipment positioned inside the protective casing,
a mobile structure capable of performing a movement relatively to the fixed structure.

The mobile structure includes at least one aperture forming a means for suction of air from the outside of the casing towards the inside of the casing when the mobile structure is moving relatively to the fixed structure, in order to cool the electronic equipment.

### BACKGROUND OF THE INVENTION

The present invention relates to an electronic system comprising:
a fixed structure including a protective casing and electronic equipment positioned inside the protective casing, and
a mobile structure, able to perform a movement relatively to the fixed structure.

The invention notably relates to a radar comprising a rotating antenna, wherein the mobile structure includes the rotating antenna.

A radar with a rotating antenna is known, such a radar comprising a fixed structure including a vertical middle axis and a mobile structure rotating around the vertical axis relatively to the fixed structure. The fixed structure includes a hermetically sealed case and electronic equipment positioned inside the case. The fixed structure includes means for driving into rotation the mobile structure, said driving means being laid out inside the case. The mobile structure includes the rotating antenna. The case is made in a heat conducting material.

During operation of the radar, cooling of the electronic equipment positioned inside the case is obtained by heat conduction from the inside of the case towards the outside via the heat conducting wall of the case on the one hand, the temperature being higher inside the case than on the outside, and by heat convection due to the movement of the air in contact with the outer surface of the case on the other hand.

However, such an electronic system does not allow sufficient thermal cooling of electronic equipment, the temperature of which gradually increases during the operation of the system. Such heating may limit the lifetime of the pieces of electronic equipment, or even cause their failure.

The object of the invention is therefore to propose an electronic system with which cooling of the electronic equipment positioned inside the fixed structure may be improved.

### SUMMARY OF THE INVENTION

For this purpose, the subject-matter of the invention is an electronic system of the aforementioned type, characterized in that the mobile structure includes at least one aperture forming a means for suction of air from the outside of the casing towards the inside of the casing when the mobile structure is moving relatively to the fixed structure, in order to cool the electronic equipment.

According to other embodiments, the electronic system comprises one or more of the following features taken individually or according to all technically possible combinations:
the movement of the mobile structure relatively to the fixed structure is a movement of rotation,
the mobile structure includes a plurality of apertures forming means for air suction,
the fixed structure includes an upper aperture, and the mobile structure includes a fairing forming a means for obturating the upper aperture and said or each suction aperture is made in the fairing of the mobile structure,
the fixed structure includes a case inside which is positioned the electronic equipment, the case being laid out inside the protective casing, and the fixed structure includes means for guiding the air received from the suction means between the case and the protective casing,
the case is hermetically sealed,
the fixed structure further includes at least one orifice for outflow of the air sucked up by the suction means,
the mobile structure includes a vane for said or each suction aperture, and
said or each vane is oriented towards the front relatively to the direction of rotation of the mobile structure relatively to the fixed structure.

The subject-matter of the invention is also a radar, as an electronic system such as defined above, comprising a rotating antenna, wherein the mobile structure includes the rotating antenna.

### BRIEF DESCRIPTION OF THE DRAWINGS

These features and advantages of the invention will become apparent upon reading the following description, only given as an example, and made with reference to the appended drawings, wherein:

FIG. 1 is a perspective view of a radar according to the invention, and

FIG. 2 is a sectional view along the plane H of FIG. 1,

### DESCRIPTION OF THE PREFERRED EMBODIMENTS

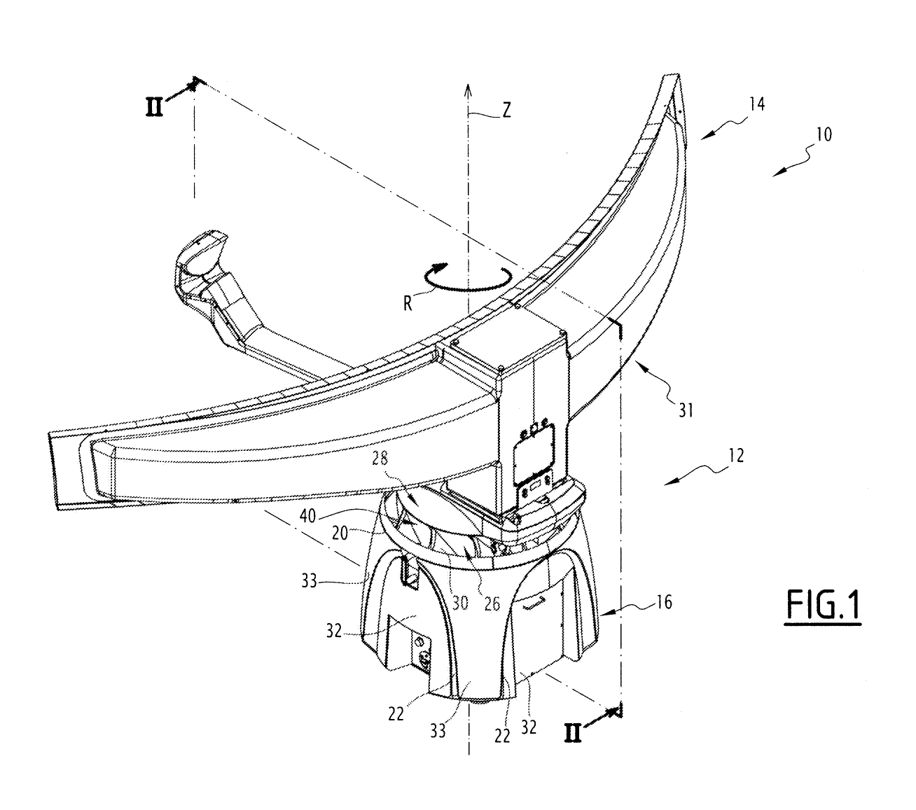

In FIG. 1, an electronic system, such as a radar with a rotating antenna, comprises a fixed structure and a mobile structure capable of performing a movement relatively to the fixed structure.

In the exemplary embodiment of FIG. 1, the movement of the mobile structure relatively to the fixed structure is a movement of rotation. More specifically, the mobile structure is mobile in rotation around a vertical middle axis Z of the fixed structure (arrow R).

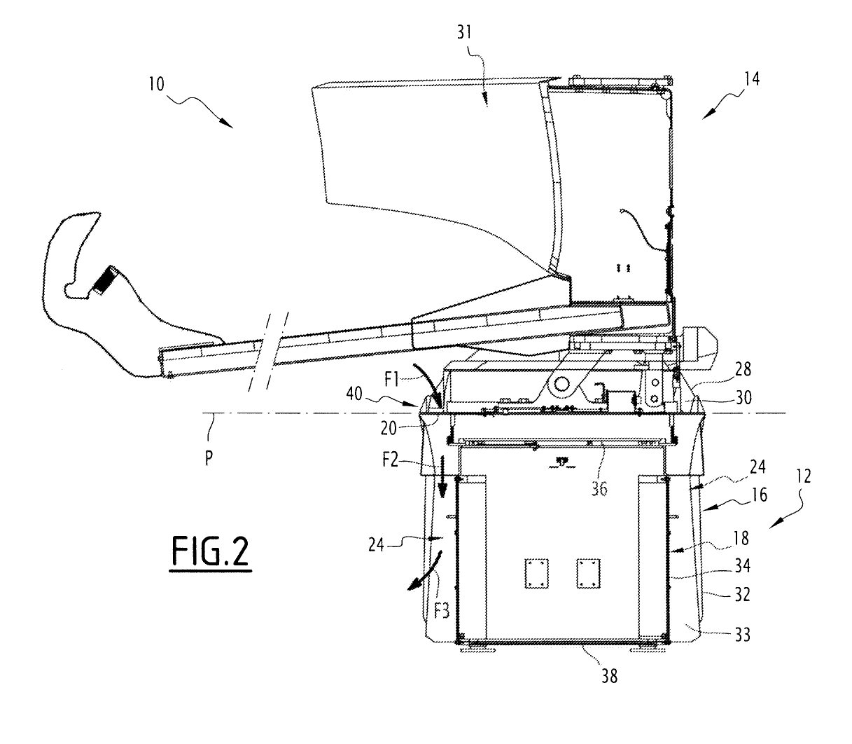

The speed of rotation of the mobile structure relatively to the fixed structure is less than one revolution per second, and is for example equal to two radians per second. The fixed structure includes a protective casing and pieces of electronic equipment, not shown, positioned inside the protective casing. In the exemplary embodiment of FIGS. 1 and 2, the fixed structure also includes a case, visible in FIG. 2, laid out inside the protective casing, the electronic equipment being itself positioned inside the case.

The fixed structure includes an upper aperture forming an air intake and at least one orifice for air outflow, visible in FIG. 1, as well as means for guiding the air between the upper aperture and the outflow orifice, as illustrated in FIG. 2.

The fixed structure for example includes four outflow orifices.

The mobile structure includes according to the invention at least one aperture forming means for suction of air from the outside of the casing towards the inside of the casing, when the mobile structure is moving relatively to the fixed structure. In the exemplary embodiment of FIGS. 1 and 2, the mobile structure includes a plurality of suction apertures.

The mobile structure includes a fairing forming a means for obturating the upper aperture of the fixed structure.

Additionally, the mobile structure includes a vane for each suction aperture, as illustrated in FIG. 1.

In the exemplary embodiment of FIGS. 1 and 2 wherein the electronic system is a radar with a rotating antenna, the mobile structure also includes a rotating antenna which is known per se.

The protective casing includes planar side walls and curved side walls, with a spacing between successively a planar wall and a curved wall, in order to form a corresponding outflow orifice between the successive walls.

The protective casing 16 is intended to protect the case from outside weather conditions such as sea spray, sand storms, or other conditions.

The protective casing has reduced thickness, smaller than that of the case.

The protective casing is for example, made in composite material. Alternatively, the protective casing is made in plastic material, or further from metal sheet flanks shaped according to the desired profile. The case is hermetically sealed in order to ensure additional protection of the electronic equipment positioned inside the case. The case is notably hermetic to air in order not to let air enter the inside of the case.

The case has a shape of a cylinder with two diametrically opposite planar side faces and includes a side wail, an upper wall and a lower wall. The side wall includes both diametrically opposite planar faces. The walls of the case have a larger thickness than that of the protective casing, the case ensuring the structural maintaining of the electronic system.

The upper aperture is formed by the upper edge of the side walls of the protective casing. The upper aperture is for example positioned in a substantially horizontal plane P, as visible in FIG. 2.

The outlet orifices are essentially positioned in the lower portion of the fixed structure away from the upper aperture.

In the exemplary embodiment of FIGS. 1 and 2, each outlet orifice has the shape of an interstice laid out between respectively a planar wall and a curved wall of the protective casing.

Alternatively or additionally, the air outflow orifices have the shape of ventilation vents, for example laid out in the lower portion of two diametrically opposite planar walls of the protective casing.

Alternatively or additionally, the air outflow orifices have the shape of through-holes made in the curved walls and/or in the planar walls, preferably in their lower portion.

The guiding means are able to guide the air received through the upper aperture from the suction apertures, as far as the air outflow orifices. The guiding means include the outer surface of the case and the inner surface of the protective casing, the latter facing each other.

Each suction aperture is made in the fairing of the mobile structure.

The suction apertures are for example distributed angularly around the vertical middle axis Z.

The suction apertures have dimensions such that the circulation of air, generated inside the casing generates lowering of the temperature by at least 10° Celsius for a speed of rotation of the mobile structure of less than one revolution per second.

The fairing is positioned in the lower portion of the mobile structure, The fairing includes a circular crown, in which are laid out the suction apertures and the vanes.

Each vane has, in addition to the suction apertures, dimensions such that the circulation of air generated inside the casing causes lowering of the temperature by at least 10° Celsius for a speed of rotation of the mobile structure of less than one revolution per second.

Each vane is oriented towards the front with regard to the direction of rotation (arrow R) of the mobile structure relatively to the fixed structure, as illustrated in FIG. 1. The vanes are thus also called action vanes, the ventilation due to the vanes and resulting from the movement of rotation of the mobile structure being ventilation with action.

The vanes are for example made in composite material. Alternatively, the vanes are made in plastic material, or further from metal sheet flanks.

The side walls are substantially vertical. The planar and curved walls are for example alternating along the periphery of the casing around the vertical axis Z.

Each planar wall is shifted sideways relatively to both neighboring curved walls, in order to form a compatible corresponding outflow orifice for the required air circulation rate. The value of the required air circulation rate is greater than or equal to 50 m³ per hour preferably equal to 55 m³ per hour.

The shift between the planar wall and both neighboring curved walls is larger in the lower portion of the casing than in the upper portion. In other words, the area of the outflow orifice is in majority partly smaller than that of the casing, so that the air outlet is essentially positioned away from the upper aperture, in order to promote air convection along the case.

Thus, when the electronic system according to the invention is operating and the mobile structure is moving, for example in rotation, relatively to the fixed structure, air is sucked up via the suction apertures and the vane from the outside of the casing towards the inside of the latter (arrow F1).

Air is then guided by the guiding means from the upper aperture as far as the air outflow orifices of the fixed structure, between the case and the protective casing (arrow F2), and more specifically along the case. The air is finally expelled through the outflow orifices (arrow F3).

In other words, the suction means and the guiding means generate during the movement of the mobile structure relatively to the fixed structure forced convection of air along the case containing the electronic equipment, which allows improvement in the thermal cooling of these pieces of electronic equipment.

Further, the protective casing protects the case from solar radiation and also limits thermal heating of said case.

The electronic system according to the invention gives the possibility of benefiting from forced air convection, in the absence of an additional fan positioned inside the casing, the suction means and the guiding means themselves forming a fan.

This thermal cooling solution for electronic equipment is therefore particularly economical, since it benefits from the movement of the mobile structure relatively to the fixed structure, this movement being moreover indispensable for the operation of the electronic system. The electronic system according to the invention does not require addition of additional motion-driving means.

The thermal cooling due to the forced convection because of the suction apertures is particularly efficient, since the temperature inside the casing is reduced by at least 10° Celsius for a speed of rotation of the mobile structure relatively to the fixed structure of less than one revolution per second, for example equal to two radians per second.

Thus, it is conceivable that the electronic system according to the invention provides improvement in the thermal cooling of electronic equipment positioned inside the protective casing, while not causing any overcost.

1. An electronic system comprising:
a fixed structure including a protective casing and electronic equipment positioned inside the protective casing,
a mobile structure, capable of performing a movement relatively to the fixed structure, the mobile structure including at least one aperture forming means for suction of air from the outside of the casing towards the inside of the casing when the mobile structure is moving relatively to the fixed structure, in order to cool the electronic equipment,
wherein the fixed structure includes an upper aperture, and the mobile structure includes a fairing forming means for obturating the upper aperture, and in that said or each suction aperture is made in the fairing of the mobile structure.

2. The system according to claim 1, wherein the movement of the mobile structure relatively to the fixed structure is a movement of rotation.

3. The system according to claim 1, wherein the mobile structure includes a plurality of apertures forming air suction means.

4. The system according to claim 1, wherein the fixed structure includes a case inside which electronic equipment is positioned, the case being laid out inside the protective casing and the fixed structure includes means for guiding the air received from the suction means between the case and the protective casing.

5. The system according to claim 4, wherein the case is hermetically sealed.

6. The system according to claim 1, wherein the fixed structure further includes at least one orifice for outflow of the air sucked up by the suction means.

7. The system according to claim 1, wherein the mobile structure includes a vane for said or each suction aperture.

8. The system according to claim 7, wherein said or each vane is oriented towards the front with regard to the direction of rotation of the mobile structure relatively to the fixed structure.

9. A radar including an electronic system according to claim 1, said electronic system comprising a rotating antenna, the mobile structure of said electronic system including the rotating antenna.
